(19) United States
(12) Patent Application Publication
(10) Pub. No.: US 2023/0253327 A1
(43) Pub. Date: Aug. 10, 2023

(54) HYBRID SUPER VIA STRUCTURE AND METHOD OF MANUFACTURING THE SAME

(71) Applicant: SAMSUNG ELECTRONICS CO., LTD., Suwon-si (KR)

(72) Inventors: Janggeun LEE, Delmar, NY (US); Kang-ill SEO, Albany, NY (US)

(73) Assignee: SAMSUNG ELECTRONICS CO., LTD., Suwon-si (KR)

(21) Appl. No.: 17/735,768

(22) Filed: May 3, 2022

Related U.S. Application Data
(60) Provisional application No. 63/308,615, filed on Feb. 10, 2022.

(51) Int. Cl. H01L 23/535; H01L 23/522; H01L 21/768

(52) U.S. Cl. CPC H01L 23/535; H01L 23/5226; H01L 21/76805; H01L 21/76843; H01L 21/76877; H01L 21/76895

(57) ABSTRACT

A connection structure of an integrated circuit may include: a top via in a 1^{st} layer; and a super via on the top via, the super via being connected to the top via, wherein the super via penetrates through a 2^{nd} layer, on the 1^{st} layer, and a 3^{rd} layer on the 2^{nd} layer, and each of the 2^{nd} layer and the 3^{rd} layer is provided for formation of at least one metal pattern or at least one via therein.

### CROSS-REFERENCE TO RELATED APPLICATION

This application is based on and claims priority from U.S. Provisional Application No. 63/308,615 filed on Feb. 10, 2022 in the U.S. Patent and Trademark Office, the disclosure of which is incorporated herein in its entirety by reference.

### BACKGROUND

### 1. Field

Apparatuses and methods consistent with example embodiments of the disclosure relate to a hybrid super via structure, and more particularly to a combination of a super via and a top via in a connection structure of an integrated circuit.

### 2. Description of the Related Art

FIG. 1 illustrates a cross-sectional view of a related-art back-end-of-line (BEOL) structure including a plurality of metal patterns and a plurality of vias. A BEOL structure 100 shown in FIG. 1 may be a part of or connected to an integrated circuit (not shown) such as a logic circuit, a memory flip-flop or a latch circuit formed of at least one semiconductor device to receive and output signals for the integrated circuit.

Hereinafter, the “via” refers to a via structure or a via plug which is formed or filled in a via hole to connect two or more metal patterns formed at vertically different stacked layers or levels. Also, the “metal pattern” refers to a metal line or a metal structure which may be connected to a circuit element such as a middle-of-line (MOL) element or a front-end-of-line (FEOL) element in a semiconductor device. For example, the metal pattern may be a power line connected to a voltage source (Vdd or Vss) to receive a positive or negative voltage supplied to a semiconductor device connected to the BEOL structure 100. As another example, the metal pattern itself may be an MOL element such as a gate contact structure connected to a gate electrode of a transistor or a source/drain contact structure connected to a source/drain region of the transistor included in the semiconductor device. Thus, the BEOL structure 100 may be actually a combination of a BEOL structure and an MOL structure.

The BEOL structure 100 shown in FIG. 1 is formed in five layers L1 to L5 stacked in a vertical direction in which a plurality of metal patterns and a plurality of vias are respectively provided. It is understood that each of the layers L1 to L5 is provided in the BEOL structure 100 to form an independent metal pattern or via structure.

Referring to FIG. 1, the 1^{st} layer L1, which is a lower metal layer, includes a lower metal pattern M1 that is connected to a transistor structure TR formed therebelow. The transistor structure TR may include one or more MOL or FEOL elements of a transistor such as a fin field-effect transistor or a nanosheet transistor. FIG. 1 also shows that the 5^{th} layer L5, which is an upper metal layer, includes an upper metal pattern M3 that may receive a power signal or may be used for internal routing of the semiconductor device. For example, the lower metal pattern M1 or the upper metal pattern M3 may be used as a power line, a gate contact structure, or a source/drain region contact structure, not being limited thereto.

FIG. 1 further shows that, to connect the lower metal pattern M1 to the upper metal pattern M3, a 1^{st} via hole VH1, a plurality of trenches T and a 2^{nd} via hole VH2 are formed in the 2^{nd} to 4^{th} layers L2-L4, respectively, and a 1^{st} via V1, a plurality of metal patterns M2 including an interconnect metal pattern, and a 2^{nd} via V2 may be formed or filled in the 1^{st} via hole VH1, the trenches T and the 2^{nd} via hole VH2, respectively. The 2^{nd} layer L2 and the 4th layer L4 each may be referred to as a via layer, and the 3^{rd} layer L3 may be referred to as a middle metal layer or an interconnect metal layer. However, although not shown, at least one other trench for another metal pattern may be formed in each of the 2^{nd} layer L2 and the 4^{th} layer L4, and at least one other via hole for at least one another via may be formed in the 3^{rd} layer L3.

Here, the 1^{st} via V1 connects the lower metal pattern M1 to the interconnect metal pattern M2, and the 2^{nd} via V2 connects the interconnect metal pattern M2 to the upper metal pattern M3. These metal patterns and vias may be formed of the same or different metals or metal compounds including at least one of copper (Cu), titanium (Ti), tantalum (Ta), aluminum (Al), tungsten (W), cobalt (Co), molybdenum (Mo), ruthenium (Ru), etc.

Further, the BEOL structure 100 includes 1^{st} to 4^{th} interlayer dielectric (ILD) structures ILD1-ILD4 formed in the 2^{nd} to 5^{th} layers L2-L5 to respectively isolate or insulate the 1^{st} via V1, the interconnect metal pattern M2, the 2^{nd} via V2, and the upper metal pattern M3 from horizontally neighboring circuit elements, if any. The 1^{st} to 4^{th} ILD structures ILD1-ILD4 may be formed of at least one of low-k materials such as silicon, carbon, silicon oxide and silicon nitride. The low-k material may have a dielectric constant (k value) that is about 3.9 or less. These ILD structures ILD1-ILD4 may include at least one of oxide, nitride and oxynitride.

In the meantime, a barrier metal line BM is layered on a bottom surface and a sidewall of each of the trenches T and the via holes VH1 and VH2 to accommodate the metal patterns M2 and the vias V1 and V2, respectively. The barrier metal line BM is provided to prevent diffusion of a material(s) such as Cu forming the metal patterns M2 and the vias V1 and V2 into the ILD structures ILD1-ILD3 that deteriorates a connection performance. The barrier metal line BM may also facilitate adhesion of the metal patterns M2 and the vias V1 and V2 to the respective layers L1-L3 where the ILD structures ILD1-ILD3 are formed. The barrier metal line may be formed of at least one of titanium (Ti), titanium oxide (TiO) and tantalum (Ta), not being limited thereto.

The BEOL structure 100 may be formed though a single or dual damascene process. The dimension of the BEOL structure 100 includes a vertical distance D between the lower and upper metal patterns M1 and M3 which is a sum of a height h2 of the interconnect metal pattern M2 and respective heights h1 and h3 of the two vias V1 and V2.

As the connection of the lower metal pattern M1 and the upper metal pattern M3 to each other requires a plurality of interconnect elements such as the interconnect metal pattern M2 and the two vias V1 and V2, the resistance/capacitance (RC) characteristics of the BEOL structure 100 are degraded to affect the performance of the semiconductor device connected to the BEOL structure 100. Further, the damascene process of manufacturing the BEOL structure 100 may be complicated due to the increased number of the interconnect elements.

Thus, there is demand of an improved connection structure or BEOL structure of a semiconductor device and a method of forming the same.

Information disclosed in this Background section has already been known to the inventors before achieving the embodiments of the present application or is technical information acquired in the process of achieving the embodiments described herein. Therefore, it may contain information that does not form prior art that is already known to the public.

### SUMMARY

The disclosure provides a connection structure of an integrated circuit and a method of designing the via structures.

According to embodiments, there is provided a connection structure of an integrated circuit which may include: a top via in a 1^{st} layer; and a super via on the top via, the super via being connected to the top via, wherein the super via penetrates through a 2^{nd} layer, on the 1^{st} layer, and a 3^{rd} layer on the 2^{nd} layer, and each of the 2^{nd} layer and the 3^{rd} layer is provided for formation of at least one metal pattern or at least one via therein.

The connection structure may further include a metal pattern or another top via in the 2^{nd} layer, wherein the metal pattern or the other top via is not connected to the super via.

The connection structure may further include: a lower metal pattern in a lower metal layer below the 1^{st} layer, the lower metal pattern being vertically connected to the top via; and an upper metal pattern in an upper metal layer on the 3^{rd} layer, the upper metal pattern being vertically connected to the super via.

According to embodiments, there is provided a semiconductor device which may include: a transistor structure; a 1^{st} metal pattern, in a 1^{st} layer, connected to the transistor structure; a top via, in a 2^{nd} layer on the 1^{st} layer, connected to the 1^{st} metal pattern; a super via including a lower portion in a 3^{rd} layer on the 2^{nd} layer and an upper portion in a 4^{th} layer on the 3^{rd} layer, the super via being connected to the top via; and a 2^{nd} metal pattern, in a 5^{th} layer on the 4^{th} layer, connected to the super via. Here, the 3^{rd} layer and the 4^{th} layer each may be provided for formation of at least one metal pattern or at least one via therein

According to embodiments, there is provided a method of manufacturing a connection structure of an integrated circuit. The method may include: forming a top via at a 2nd layer on a 1^{st} metal pattern at a 1^{st} layer; forming a super via on the top via, the super via including a lower portion at a 3^{rd} layer and an upper portion at a 4^{th} layer; and forming a 2nd metal pattern, at a 5^{th} layer on the 4^{th} layer, connected to the super via, wherein the super via has an aspect ratio of width and height greater than the aspect ratio of the top via.

### BRIEF DESCRIPTION OF DRAWINGS

Example embodiments of the disclosure will be more clearly understood from the following detailed description taken in conjunction with the accompanying drawings in which:

FIG. 1 illustrates a cross-sectional view of a related-art back-end-of-line (BEOL) structure including a plurality of metal patterns and a plurality of vias;

FIG. 2 illustrates a cross-sectional view of a BEOL structure including a plurality of metal patterns and a super via, according to an embodiment;

FIG. 3 illustrates a BEOL structure including a plurality of metal patterns and a hybrid via structure formed of a combination of a super via and a top via, according to an embodiment;

FIGS. 4A to 4J illustrate cross-sectional views of a method for manufacturing a BEOL structure including a plurality of metal patterns and a hybrid via structure, according to embodiments;

FIGS. 5A to 5C illustrate a single damascene process to form a top via V on a lower metal pattern, according to embodiments

FIG. 6 illustrates a flowchart of the method described in reference to FIGS. 4A to 4J; and

FIG. 7 is a schematic block diagram illustrating an electronic device including a semiconductor device, according to an example embodiment.

### DETAILED DESCRIPTION OF EMBODIMENTS

The embodiments described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure. For example, even if matters described in a specific example or embodiment are not described in a different example or embodiment thereto, the matters may be understood as being related to or combined with the different example or embodiment, unless otherwise mentioned in descriptions thereof. In addition, it should be understood that all descriptions of principles, aspects, examples, and embodiments of the disclosure are intended to encompass structural and functional equivalents thereof. In addition, these equivalents should be understood as including not only currently well-known equivalents but also equivalents to be developed in the future, that is, all devices invented to perform the same functions regardless of the structures thereof. For example, a material or materials forming a metal pattern, a via or super via may not be limited to metals of which examples are taken herein as long as the disclosure can be applied thereto. Further, the use of the super via scheme described herein may not be limited to the BEOL of a semiconductor device, and instead, may be applied to a different structure or device.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

Spatially relative terms, such as “over,” “above,” “on,” “upper,” “below,” “under,” “beneath,” “lower,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures. For example, if the semiconductor device in the figures is turned over, elements described as “below” or “beneath” other elements would then be oriented “above” the other elements. Thus, the term “below” can encompass both an orientation of above and below. The semiconductor device may be otherwise oriented (rotated 90 degrees or at other orientations) and the spatially relative descriptors used herein interpreted accordingly.

As used herein, expressions such as “at least one of” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be also understood that, even if a certain step or operation of manufacturing an apparatus or structure is described later than another step or operation, the step or operation may be performed later than the other step or operation unless the other step or operation is described as being performed after the step or operation.

Many embodiments are described herein with reference to cross-sectional illustrations that are schematic illustrations of the embodiments (and intermediate structures). As such, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept. Further, in the drawings, the sizes and relative sizes of layers and regions may be exaggerated for clarity.

For the sake of brevity, conventional elements of an integrated circuit, a semiconductor device and a connection structure such as a BEOL structure may or may not be described in detail herein or shown in the drawings. For example, a barrier metal line formed in a via hole or a trench before a via or a metal structure is formed therein may not be shown in the drawings. An etch stop layer formed between two vertically adjacent layers may also not be shown in the drawings. Thus, a height or length of a layer or a via and a super via formed in the layer as described herein and shown in the drawings may include the height or thickness of the etch stop layer.

A super via scheme has been introduced to address the above problems occurring from the BEOL structure 100 including a plurality of metal patterns and vias formed in a plurality of different layers or levels, and the damascene process of manufacturing the BEOL structure 100.

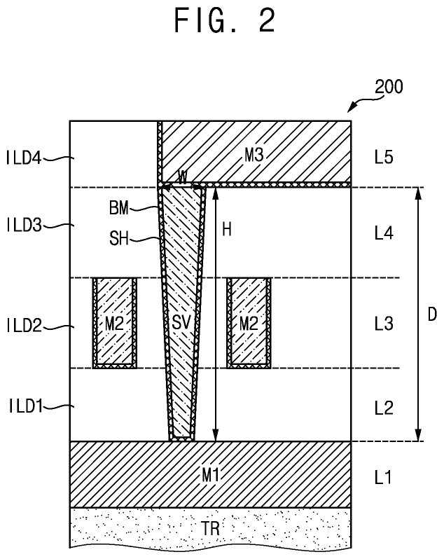

FIG. 2 illustrates a cross-sectional view of a BEOL structure including a plurality of metal patterns and a super via, according to an embodiment.

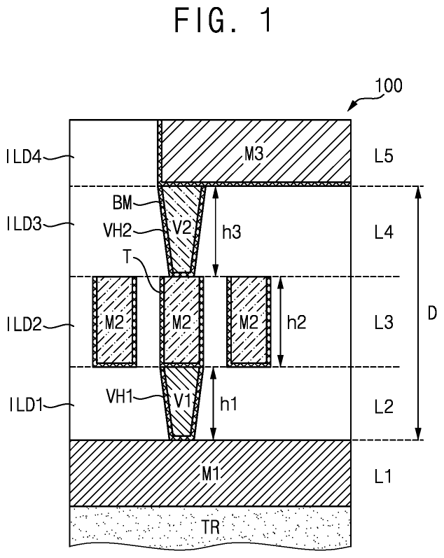

Herein, the “super via” refers to a via connecting two metal patterns or a metal pattern and a via, to each other, formed in two vertically non-adjacent layers across two or more layers therebetween, or. In contrast, the vias V1 and V2 formed in the BEOL structure 100 shown in FIG. 1 may be referred to as a “a standard via” or a “regular via” which connects two metal patterns or a metal pattern and a via, to each other, formed in two vertically adjacent layers or two vertically non-adjacent layers across one layer therebetween.

Referring to FIG. 2, a BEOL structure 200 may also be formed of five layers L1-L5 stacked in the vertical direction, similar to the BEOL structure 100 shown in FIG. 1. The BEOL structure 200 may include the same lower metal pattern M1 and the same upper metal pattern M3 provided in the 1^{st} layer L1 and the 5^{th} layer L5, respectively, and the same 1^{st} to 4th ILD structures ILD1-ILD4 as those of the BEOL structure 100. For example, the lower metal pattern M1 or the upper metal pattern M3 may be used as a power line, a gate contact structure, or a source/drain region contact structure of a transistor structure TR of a semiconductor device formed below the lower metal pattern M1, not being limited thereto. Also, the materials forming the metal patterns M1 and M3 may be at least one of Cu, Ti, Ta, Al, W, Co, Mo, Ru, etc., and the materials forming the ILD structures ILD1-ILD4 may include at least one of oxide, nitride and oxynitride. Thus, duplicate descriptions thereof are omitted herein.

According to an embodiment, the BEOL structure 200 may include a super via SV in a super via hole SH penetrating the 2^{nd} to 4^{th} layers L2-L3 to replace the combination of the interconnect metal pattern M2 and the two vias V1 and V2 of the BEOL structure 100, to connect the lower metal pattern M1 to the upper metal pattern M3. The connection of the two metal patterns M1 and M3 through the super via SV may be insulated by the 1^{st} to 3^{rd} ILD structures ILD1-ILD3.

FIG. 2 also shows that the 3^{rd} layer L3 of the BEOL structure 200 includes the same plurality of metal patterns M2 in trenches T like in the BEOL structures 100 except the interconnect metal pattern M2 which is replaced by the super via SV. Instead of the plurality of metal patterns M2, a plurality of vias may be formed in or through the 3^{rd} layer L3, according to an embodiment. Further, FIG. 2 shows that a barrier metal line BM may be formed on a bottom surface and a sidewall of the super via hole SH as well as each of the trenches T to accommodate the super via SV and the metal patterns M2, respectively, for the same purpose of the barrier metal line BM shown in FIG. 1. This barrier metal line BM may be formed of at least one of Ti, TiO and Ta, not being limited thereto.

The materials forming the super via SV may be the same as those of the 1^{st} and 2^{nd} vias V1 and V2, according to an embodiment.

The super via SV of the BEOL structure 200 has an advantage over the interconnect elements of the BEOL structure 100 in terms of resistance/capacitance (RC) characteristics. For example, the resistance occurring from the super via SV is lower than the resistance from the combination of the metal pattern M2, the vias V1 and V2. This is because a barrier metal line BM formed in the super via hole SH for the super via SV is shorter than a sum of the barrier metal lines BM formed in the vertically connected trench T and the via holes VH1 and VH2 for the metal pattern M2, the vias V1 and V2. That is, in the BEOL structure 100 of FIG. 1, the barrier metal lines BM are formed on vertical interfaces of the via holes VH1, the trench T and the via V2 as well as on their side walls, while the super via hole SH may need the barrier metal line BM only on its sidewall.

The super via SV of the BEOL structure 200 may also address a problem of possible misalignment between the via V1, the metal pattern M2 and the via V2 in the BEOL structure 100 of FIG. 1 to achieve an improved interconnection between the lower metal pattern M1 and the upper metal pattern M3. Further, one single structure of the super via SV can replace the plurality of interconnect elements to form a connection between the lower and upper metal patterns M1 and M3, thereby simplifying a BEOL process for a semiconductor device.

However, the super via SV is formed in the super via hole SH having a greater aspect ratio of a width W and the height H compared to the aspect ratio of the via holes V1H and V2H. Here, the width W may be a width of a top surface of the super via SV, and the height H may be a vertical distance between the top surface and a bottom surface of the super via SV. An aspect ratio of the via hole V1H or V2H may be 2, while an aspect ratio of the super via hole SH may be greater than 6, according to an embodiment. This structure of the super via hole SH causes difficulties in the reactive ion etching process to obtain the super via hole SH. Further, a void may be generated inside the super via hole SH during metallization of the super via SV therein because of the high aspect ratio, which may incur misalignment or disconnection between the lower metal pattern M1 and the upper metal pattern M3.

Thus, a different type of super via is introduced below to address the problems of the above-described super via SV of the BEOL structure 200.

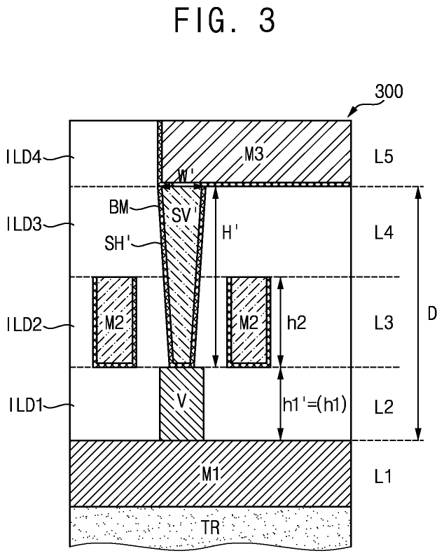

FIG. 3 illustrates a BEOL structure including a plurality of metal patterns and a hybrid via structure formed of a combination of a super via and a top via, according to an embodiment.

Referring to FIG. 3, a BEOL structure 300 may also be formed of five layers L1-L5 stacked in the vertical direction, similar to the BEOL structure 200 shown in FIG. 2. The BEOL structure 300 may include the same lower metal pattern M1 and the same upper metal pattern M3 provided in the 1^{st} layer L1 and the 5^{th} layer L5, respectively, and the same 1^{st} to 4th ILD structures ILD1-ILD4 as those of the BEOL structure 100. For example, the lower metal pattern M1 or the upper metal pattern M3 may be used as a power line, a gate contact structure, or a source/drain region contact structure of a transistor structure TR of a semiconductor device formed below the lower metal pattern M1, not being limited thereto. Also, the materials forming the metal patterns M1 and M3 may be at least one of Cu, Ti, Ta, Al, W, Co, Mo, Ru, etc., and the materials forming the ILD structures ILD1-ILD4 may include at least one of oxide, nitride and oxynitride. Thus, duplicate descriptions thereof are omitted herein.

Referring to FIG. 3, a BEOL structure 300 according to the present embodiment may include a hybrid via structure formed of a combination of a super via SV′ connected from the upper metal pattern M3 and a top via V formed on the lower metal pattern M1 to connect the two metal pattern M1 with the same upper metal pattern M3.

According to an embodiment, the super via SV′ of the BEOL structure 300 may be formed to vertically penetrate the 3^{rd} layer L3 and the 4^{th} layer L4 while the super via SV of the BEOL structure 200 vertically penetrate the 2^{nd} to 4^{th} layers L2-L3. According to an embodiment, the super via SV′ may replace the interconnect metal pattern M2 and the 2^{nd} via V2 of the BEOL structure 100. According to an embodiment, the super via SV′ may also replace an upper portion of the super via SV in the 3^{rd} layer L3 and the 4^{th} layer L4 in the BEOL structure 200.

Thus, the super via SV′ of the BEOL structure 300 may have a height H′ which is equal to a sum of the respective heights h2 and h3 of the interconnect metal pattern M2 and the second via V2 in the BEOL structure 100. The height H′ of the super via SV′ may also be smaller than the height H of the super via SV of the BEOL structure 200. However, in order to match the height H of the super via SV of the BEOL structure 200 for the vertical connection of the lower metal pattern M1 to the upper metal pattern M3, the top via V may be formed on the lower metal pattern M1 to be vertically connected to the super via SV′ disposed thereabove.

According to an embodiment, the top via V may have a height h1′ which is equal to the height h1 of the 1^{st} via V1 of the BEOL structure 100. The top via V may be referred to as a “top via” because this via structure may be formed on a top surface of the lower metal pattern M1.

FIG. 3 also shows that the 3^{rd} layer L3 of the BEOL structure 300 includes the same plurality of metal patterns M2 in trenches T like in the BEOL structures 100 and 200 except the interconnect metal pattern M2 which is replaced by the lower portion of the super via SV′. Instead of the plurality of metal patterns M2, a plurality of vias may be formed in the 3^{rd} layer L3, according to an embodiment. Further, FIG. 3 shows that a barrier metal line BM may be formed in the super via hole SH′ as well as each of the trenches T to accommodate the super via SV′ and the metal patterns M2, respectively, for the same purpose of the barrier metal line BM shown in FIG. 1. This barrier metal line BM may be formed of at least one of Ti, TiO and Ta, not being limited thereto.

In the meantime, FIG. 3 shows that the top via V takes a rectangular pillar shape formed on the lower metal pattern M1 while the 1^{st} via V1 on the lower metal pattern M1 of the BEOL structure 100 show in FIG. 1 takes a tapered pillar shape. However, this is only an example, and thus, the shape of the top via V may not be limited to the rectangular pillar shape. Thus, the top via V may be referred to as a pillar, a protrusion or a metal protrusion from the lower metal pattern M1, not being limited thereto.

Here, it is noted that an aspect ratio of a width W′ and the height H′ of the super via SV′ of the BEOL structure 300 is smaller than the aspect ratio of the width W and the height H of the super via SV of the BEOL structure 200 because of the smaller height H′ of the super via SV′, although a width W′ of the super via SV′ is equal to the width W of the super via SV. Thus, it may be easier to form the super via SV′ in the BEOL structure 300 without much concerns about the manufacturing difficulties described above with regard to the super via SV in the BEOL structure 200. In other words, the burden of implementing the reactive ion etching process to form the super via SV′ may be reduced and the void defect may also be prevented in a super via hole SH′ where the super via SV′ is filled in. Still however, the super via SV′ in the BEOL structure 300 has the same advantages of the super via SV in the BEOL structure 200 over the vias V1 and V2 of the BEOL structure 100.

Moreover, the barrier metal line BM may not be required at an interface between the top via V and the ILD structure ILD1 in the 2^{nd} layer L2. Thus, the RC characteristics of the BEOL structure 300 may be improved compared to the BEOL structure 200 in which the barrier metal line BM is formed at a sidewall of a portion of the super via SV in the 2^{nd} layer L2.

The super via SV′ and the top via V may be formed of at least one of Cu, Ti, Ta, Al, W, Co, Mo, Ru, etc., that may also form the metal patterns M1 and M3. However, the materials forming the super via SV1, the top via V, and the metal patterns M1 and M3 may be different from one another, according to an embodiment.

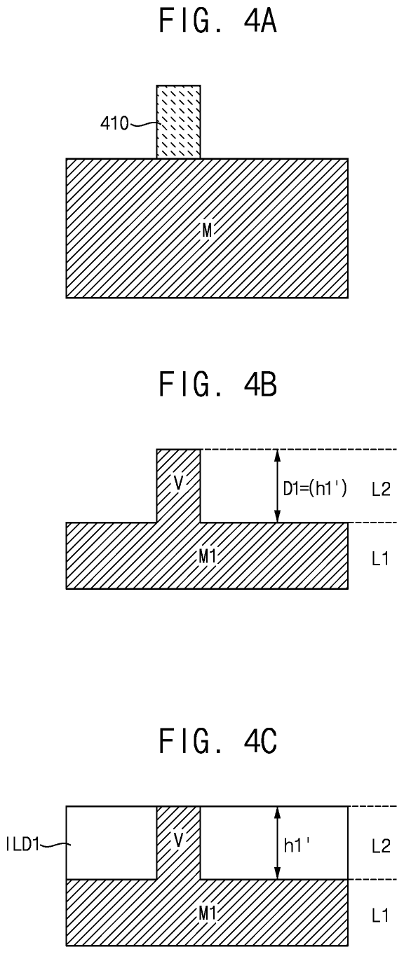

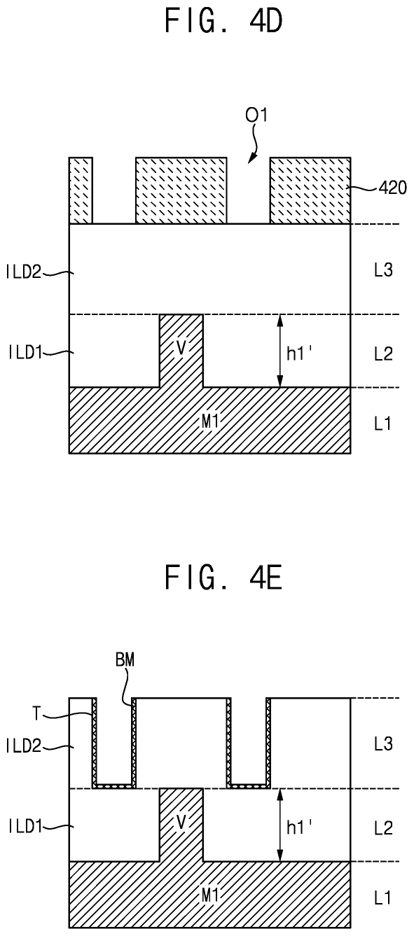

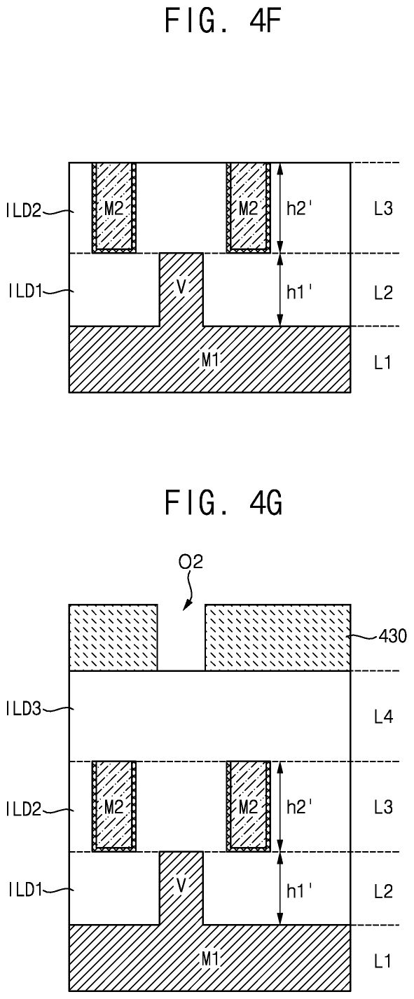

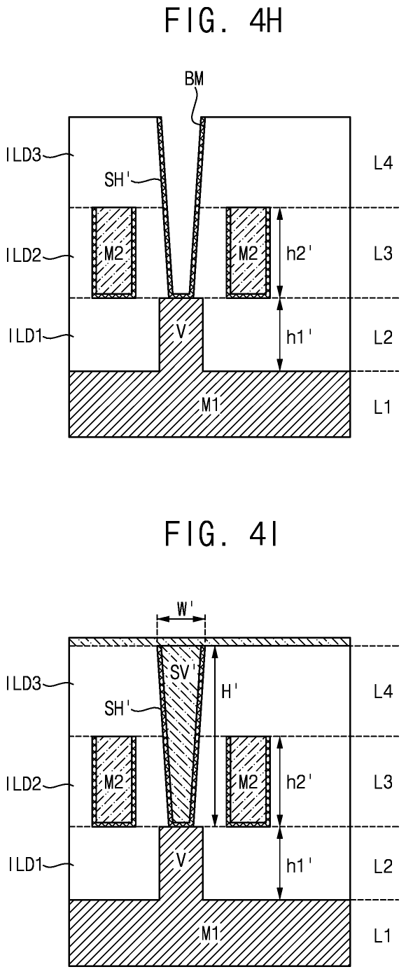

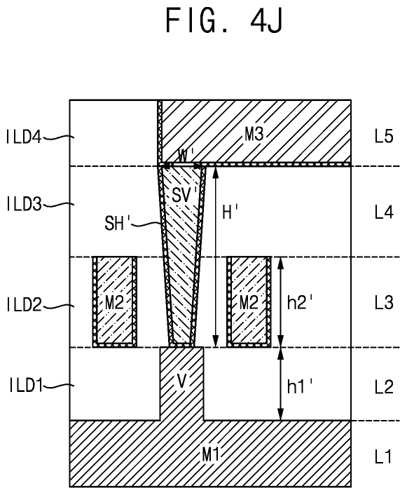

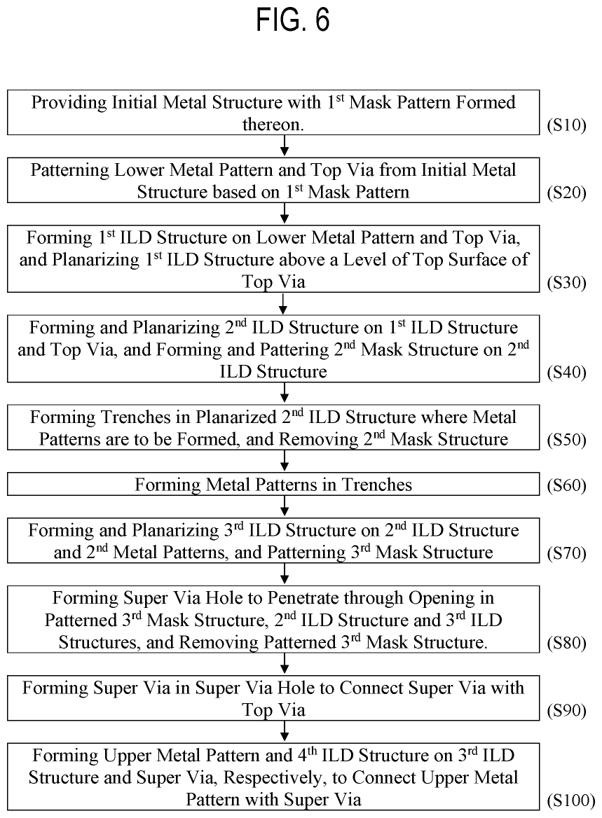

FIGS. 4A to 4J illustrate cross-sectional views of a method for manufacturing a BEOL structure including a plurality of metal patterns and a hybrid via structure, according to embodiments. FIG. 6 illustrates a flowchart of the method described in reference to FIGS. 4A to 4J.

It is understood here that FIGS. 4A to 4J show a plurality of operations of the method for manufacturing the BEOL structure 300 shown in FIG. 3, and these operations may not be limited to the order presented herein.

Referring to FIG. 4A, an initial metal structure may be provided with a 1^{st} mask pattern formed thereon (S10 in FIG. 6).

According to an embodiment, a 1^{st} mask pattern 410 may be formed on an initial metal structure M where a top via is to etched out from the initial metal structure M using the 1st mask pattern 410.

The initial metal structure M may include at least one of Cu, Ti, Ta, Al, W, Co, Mo, Ru, etc. The 1^{st} mask pattern 410 may be formed of at least one of aluminum oxide (AlOₓ), aluminum nitride (AlN), aluminum oxynitride (AlON), silicon dioxide (SiO₂), silicon oxynitride (SiON) and SiCN. Although not shown, the 1^{st} mask pattern 410 may be formed on the initial metal structure M through, for example, a photolithography masking process.

Referring to FIG. 4B, a lower metal pattern and a top via may be patterned from the initial metal structure shown in FIG. 4A based on the Pt mask pattern shown in FIG. 4A (S20 in FIG. 6).

According to an embodiment, the initial metal structure M except a portion thereof below the 1^{st} mask pattern 410 may be removed to a predetermined depth D1 from a top surface of the initial metal structure M through dry etching (e.g., reactive ion etching, plasma etching, ion beam etching, or laser ablation). By this etching operation, a lower metal pattern M1 may be obtained in a 1^{st} layer L1, which is the lower metal layer of the BEOL structure 300, and a top via V having a height h1′ equal to the predetermined depth D1 may be obtained in a 2nd layer L2, which is a via layer, above the 1^{st} layer L1. Here, the height h1′ may also be equal to the height h1 of the 1^{st} via V1 in the BEOL structure 100 shown in FIG. 1.

According to an embodiment, the top via V may take a shape of a rectangular protrusion on the top surface of the lower metal pattern M1 because a rectangular shape of the 1st mask pattern 410 is mirrored or transferred down to the initial metal structure M in the present operation. Thus, a width of the top via V may be equal to a width of the 1^{st} mask pattern 410 on the initial metal structure M.

After the top via V is formed on the lower metal pattern M1, the 1^{st} mask pattern 410 may be removed, for example, by an ashing operation such as plasma ashing.

Referring to FIG. 4C, a 1^{st} ILD structure may be layered on the lower metal pattern and the top via shown in FIG. 4B, and the 1^{st} ILD structure above a level of a top surface of the top via may be planarized (S30 in FIG. 6).

In this operation, a 1^{st} ILD structure ILD1 may be layered on a top surface of the lower metal pattern M1 and on a sidewall of the top via V, and the 1^{st} ILD structure ILD1 above a level of a top surface of the top via V may be planarized to expose the top surface of the top via V.

According to embodiments, the 1^{st} ILD structure ILD1 may be layered on the lower metal pattern M1 and the top via V by a deposition process such as chemical vapor deposition (CVD), physical vapor deposition (PVD), plasma-enhanced chemical vapor deposition (PECVD), atomic layer deposition (ALD), not being limited thereto, and then, a portion of the 1^{st} ILD structure ILD1 above the level of the top surface of the top via may be removed by a process such as chemical-mechanical polishing (CMP), not being limited thereto, to expose the top surface of the top via V, which is to be connected to a super via to be formed in a later step.

According to an embodiment, the 1^{st} ILD structure ILD1 may surround a sidewall of the top via V to insulate the top via V from at least circuit elements arranged at the same L2 layer (via layer). The 1^{st} ILD structure ILD1 may be formed of at least one of low-k materials such as silicon, carbon, silicon oxide and silicon nitride. The 1^{st} ILD structure ILD1 may include at least one of oxide, nitride and oxynitride.

As the top via V is formed in the above etching operations S10 to S30 which does not require metal deposition in a via hole, no barrier metal line may be formed between the top via V and the 1^{st} ILD structure ILD1 in the 2^{nd} layer L2, thereby improving RC characteristics of a BEOL structure to be formed using the top via V.

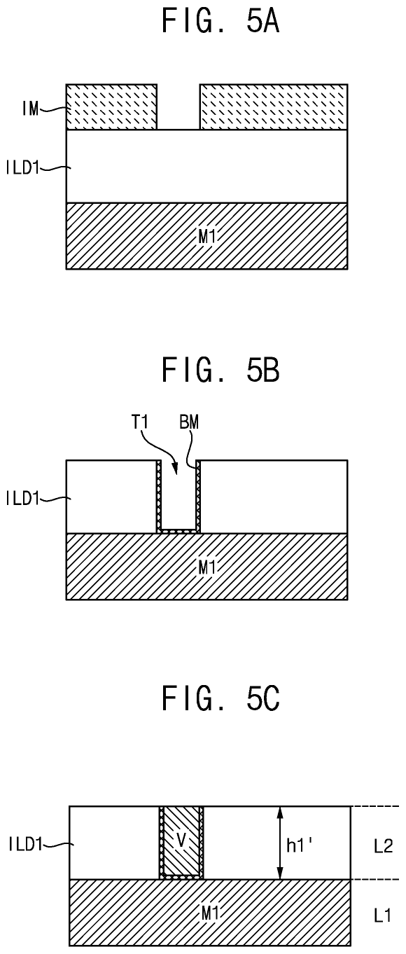

The top via V formed on the lower metal pattern M1 and surrounded by the 1st ILD structure ILD1 may be obtained through a process different from operations S10 to S30 shown in FIGS. 5A and 5C.

FIGS. 5A to 5C illustrate a single damascene process to form the top via Von the lower metal pattern M1, according to embodiments.

Referring to FIG. 5A, the 1^{st} ILD structure ILD1 may be provided and planarized on the lower metal pattern M1, and an initial mask pattern IM may be provided on the 1^{st} ILD structure ILD1 to have an opening O which exposes a portion of a top surface of the Pt ILD structure ILD1 below which the top via V is to be formed. The initial mask pattern IM with the opening may be formed by, for example, a photolithography masking process.

Referring to FIG. 5B, the 1^{st} ILD structure ILD1 may be patterned to obtain a via hole VI exposing a top surface of the lower metal pattern M1 using the initial mask pattern IM, and a barrier metal line BM may be layered in the trench T1. Subsequently, the initial mask pattern IM may be removed by, for example, an ashing operation such as plasma ashing.

Referring to FIG. 5C, the top via V may be formed in the via hole VI to be connected to the lower metal pattern M1. The formation of the top via V may be performed by, for example, depositing one or more selected metal materials including at least one of Cu, Ti, Ta, Al, W, Co, Mo, Ru, etc. using at least one of CVD, PVD, PECVD and/or ALD.

Thus, while the top via V formed though the operations S10 to S20 may be a continuous metal structure without a connection surface between the top via V and the lower metal pattern M1, the top via V formed though the above damascene process (FIGS. 5A to 5C) may not be a continuous metal structure but a combination of the top via V and the lower metal pattern M1 having a connection surface along with the barrier metal line BM as shown in FIG. 5C.

Now, referring to FIG. 4D subsequent to FIG. 4C for operation S30, a 2^{nd} ILD structure may be layered and planarized on the 1^{st} ILD structure and the top via shown in FIG. 4C, and a 2^{nd} mask structure may be formed and patterned on the 2^{nd} ILD structure (S40 in FIG. 6).

In this operation, a 2^{nd} ILD structure ILD2 may be formed on the 1^{st} ILD structure ILD1 and the top via V surrounded by the 1^{st} ILD structure ILD1, and the 2^{nd} ILD structure ILD2 may be planarized. Further, the 2^{nd} mask structure 420 may be formed on the planarized 2^{nd} ILD structure ILD2, and patterned to provide a plurality of openings O1 on the planarized 2^{nd} ILD structure ILD2 at positions below which a plurality of metal patterns M2 may be formed. The openings O1 may not be formed at a position below which the top via V is formed to be connected to a super via to be formed in a later step. The patterning of the 2^{nd} mask structure 420 may be performed through, for example, another photolithography masking process.

This formation of the 2^{nd} ILD structure ILD2 and the patterning of the 2^{nd} mask structure 420 may provide a 3^{rd} layer L3 (middle or interconnect metal layer) where the metal patterns M2 are to be formed.

The 2^{nd} ILD structure ILD2 may be formed at least one of silicon, carbon, silicon oxide and silicon nitride, which may be the same as or different from the material forming the Pt ILD structure ILD1. The 2^{nd} mask structure 420 may be formed of at least one of AlOₓ, AlN, AlON, SiO₂, SiON and SiCNa, which may be the same or different from the material forming the 1^{st} mask pattern 410.

Referring to FIG. 4E, a plurality of trenches T may be formed in the planarized 2^{nd} ILD structure shown in FIG. 4D where a plurality of metal patterns are to be formed, and the 2^{nd} mask structure patterned in the previous operation may be removed (S50 in FIG. 6).

In this operation, a plurality of trenches T may be formed in the planarized 2nd ILD structure ILD 2 where the metal patterns M2 are to be formed, and a barrier metal line BM may be layered in the trenches T. Subsequently, the patterned 2^{nd} mask structure 420 may be removed. The formation of the trenches T may be performed by another dry etching (e.g., reactive ion etching, plasma etching, ion beam etching, or laser ablation), and the barrier metal line BM may be formed through, for example, atomic layer deposition (ALD) using at least one of Ti, TiO and Ta, not being limited thereto. The removal of the patterned 2^{nd} mask structure 420 may be performed through, for example, ashing such as plasma ashing.

Referring to FIG. 4F, a plurality of metal patterns may be formed in the trenches formed in the operation of FIG. 4E (S60 in FIG. 6).

In the present operation, the metal patterns M2 may be formed in the trenches T by depositing therein one or more selected metal materials including at least one of Cu, Ti, Ta, Al, W, Co, Mo, Ru, etc. through, for example, CVD, PVD, PECVD and/or ALD. Here, each of the metal patterns M2 may have a height h2′ which is equal to the height h2 of the metal pattern M2 in the BEOL structure 100 and the BEOL structure 200.

As the metal patterns M2 are formed in the trenches T in the 2^{nd} ILD structure ILD2, sidewalls of the metal patterns M2 may be surrounded by the 2^{nd} ILD structure ILD2 to be insulated from at least one circuit element arranged in the same L3 layer (middle metal layer).

Through this operation of forming the metal patterns M2 in the trenches T, top surfaces of the metal patterns M2 may be exposed, while side walls of the metal patterns M2 may be surrounded by the 2^{nd} ILD structure.

The formation of the metal patterns M2 in operations S40 to S60 may be referred to a single damascene process.

Referring to FIG. 4G, a 3^{rd} ILD structure may be layered and planarized on the 2nd ILD structure and the 2^{nd} metal patterns, and a 3^{rd} mask structure may be patterned on the 3rd ILD structure (S70 in FIG. 6).

In this operation, a 3^{rd} ILD structure IL3 may be layered on the 2^{nd} ILD structure ILD2 and the 2^{nd} metal patterns M2 surrounded by the 2^{nd} ILD structure ILD 2, and planarized. Further, a 3^{rd} mask structure 430 may be formed on the planarized 3^{rd} ILD structure ILD3, and patterned to provide an opening O2 on the planarized 3^{rd} ILD structure ILD3 at positions below which a super via SV′ may be formed. The patterning of the 3^{rd} mask structure 430 may be performed through another photolithography masking process.

This formation of the 3^{rd} ILD structure ILD3 and the patterning of the 3^{rd} mask structure 430 may be performed to provide a 3^{rd} layer L3 (via layer) through which the super via SV′ to be formed is to penetrate in a later step.

The 3^{rd} ILD structure ILD3 may be formed at least one of silicon, carbon, silicon oxide and silicon nitride, which may be the same as or different from the material forming the Pt and 2^{nd} ILD structures ILD1 and ILD2. The 3^{rd} mask structure 430 may be formed of at least one of AlOₓ, AlN, AlON, SiO₂, SiON and SiCNa, which may be the same or different from the material forming the 1^{st} and 2^{nd} mask structures 410 and 420.

Referring to FIG. 4H, a super via hole may be formed to penetrate through the opening in the patterned 3^{rd} mask structure, the 2^{nd} ILD structure and the 3^{rd} ILD structure, and the patterned 3^{rd} mask structure may be removed (S80 in FIG. 6).

In this operation, a super via hole SH′ may be formed to penetrate through the opening O2 in the patterned 3^{rd} mask structure 430, the 2^{nd} ILD structure ILD2 and the 3^{rd} ILD structures ILD3 to expose a top surface of the top via V in the super via hole SH′, and a barrier metal line BM may be layered in the super via hole SH′. Subsequently, the patterned 3^{rd} mask structure 430 may be removed.

The formation of the super via hole SH′ may be performed by another dry etching (e.g., reactive ion etching, plasma etching, ion beam etching, or laser ablation). The removal of the patterned 3^{rd} mask structure 430 may be performed through, for example, ashing such as plasma ashing.

Referring to FIG. 4I, the super via may be formed in the super via hole formed in the operation of FIG. 4H (S90 in FIG. 6).

In this operation, a super via SV′ may be filled in the super via hole SH′ formed in the previous operation by depositing one or more selected metal materials including at least one of Cu, Ti, Ta, Al, W, Co, Mo, Ru, etc. in the trench through, for example, CVD, PVD, PECVD and/or ALD. The super via SV′ may be connected to the top surface of the top via V in this operation.

As the super via SV′ is formed in the super via SH′ continuously penetrating the 2^{nd} ILD structure ILD2 and the 3^{rd} ILD structure ILD3, a sidewall of the super via SV′ may be surrounded by the 2^{nd} ILD structure ILD2 and the 3^{rd} ILD structures ILD3 to be insulated from at least one circuit element arranged in the same L3 layer (middle metal layer) and L4 layer (via layer).

Through this operation of filling the super via SV′ in the super via hole SH′, an overfill of the super via SV′ may remain on the top surfaces of the ILD structure ILD3. This overfill of the super via SV′ may be removed by ashing or planarization using, for example, CMP to expose a top surface of the super via SV′ in the super via hole SH′. At this time, side walls of the super via SV′ may be surrounded by the 2^{nd} ILD structure ILD2 and the 3^{rd} ILD structure ILD3.

The formation of the super via SV′ in operations S70 to S90 may be referred to another single damascene process.

Referring to FIG. 4J, an upper metal pattern and a 4^{th} ILD structure may be formed on the 3^{rd} ILD structure and the super via, respectively, to connect the upper metal pattern to the super via (S100 in FIG. 6).

After removing the overfill of the super via SV′ in the previous operation, an upper metal pattern M3 and a 4^{th} ILD structure ILD4 may be formed on the 3^{rd} ILD structure and the top surface of the super via SV′, respectively, so that the upper metal pattern M3 is connected to the super via SV′ which is connected to the lower metal pattern M1 through the top via V. Thus, a BEOL structure shown in FIG. 4J may be the same as the BEOL structure 300 shown in FIG. 3.

Although not shown, the upper metal pattern M3 and the 4^{th} ILD structure ILD4 may be formed through a single damascene process.

Thus far, a structure of a hybrid via structure formed of a combination of a super via and a top via and methods of manufacturing a BEOL structure including the hybrid via structure have been described. This BEOL structure according to the above embodiments may be included in various types of electronic device.

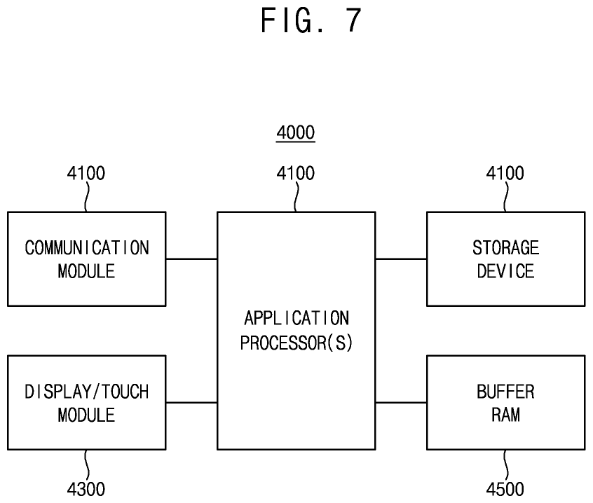

FIG. 7 is a schematic block diagram illustrating an electronic device including a semiconductor device in which a BEOL structure shown in FIG. 3 is applied, according to an example embodiment.

Referring to FIG. 7, an electronic device 4000 may include at least one application processor 4100, a communication module 4200, a display/touch module 4300, a storage device 4400, and a buffer random access memory (RAM) 4500. The electronic device 4000 may be a mobile device such as a smartphone or a tablet computer, not being limited thereto, according to embodiments.

The application processor 4100 may control operations of the mobile device 4000. The communication module 4200 is implemented to perform wireless or wire communications with an external device. The display/touch module 4300 is implemented to display data processed by the application processor 4100 and/or to receive data through a touch panel. The storage device 4400 is implemented to store user data. The storage device 4400 may be an embedded multimedia card (eMMC), a solid state drive (SSD), a universal flash storage (UFS) device, etc. The storage device 4400 may perform caching of the mapping data and the user data as described above.

The buffer RAM 4500 may temporarily store data used for processing operations of the mobile device 4000. For example, the buffer RAM 4500 may be volatile memory such as double data rate (DDR) synchronous dynamic random access memory (SDRAM), low power double data rate (LPDDR) SDRAM, graphics double data rate (GDDR) SDRAM, Rambus dynamic random access memory (RDRAM), etc.

At least one component in the mobile device 4000 may include at least one of the BEOL structure 300 including the hybrid via structure formed of a combination of the super via SV′ and the top via V to connect the lower and upper metal patterns M1 and M3.

The foregoing is illustrative of exemplary embodiments and is not to be construed as limiting the inventive concept. Although a few exemplary embodiments have been described, those skilled in the art will readily appreciate that many modifications are possible in the above embodiments without materially departing from the inventive concept.

What is claimed is:

1. A connection structure of an integrated circuit, the connection structure comprising:
a top via in a 1^{st} layer; and
a super via on the top via, the super via being connected to the top via,
wherein the super via penetrates through a 2^{nd} layer, on the 1^{st} layer, and a 3^{rd} layer on the 2^{nd} layer, and
wherein each of the 2^{nd} layer and the 3^{rd} layer is a layer where at least one metal pattern or at least one via is configured to be formed.

2. The connection structure of claim 1, further comprising a metal pattern or another top via in the 2^{nd} layer,
wherein the metal pattern or the other top via is insulated from the super via.

3. The connection structure of claim 1, further comprising a lower metal pattern in a lower metal layer below the 1^{st} layer, the lower metal pattern being vertically connected to the top via.

4. The connection structure of claim 3, wherein the lower metal pattern comprises a contact structure connected to a gate electrode or a source/drain region of a transistor.

5. The connection structure of claim 3, further comprising an upper metal pattern in an upper metal layer on the 3^{rd} layer, the upper metal pattern being vertically connected to the super via.

6. The connection structure of claim 5, wherein the lower metal pattern comprises a contact structure connected to a gate electrode or a source/drain region of a transistor, and
wherein the upper metal pattern comprises a power line connected to a voltage source.

7. The connection structure of claim 1, further comprising 1^{st} to 3^{rd} interlayer dielectric (ILD) structures in the 1^{st} to 3^{rd} layers, respectively,
wherein the 1^{st} to 3^{rd} ILD structures are on sidewalls of the top via and the super via.

8. The connection structure of claim 1, wherein the super via is a single damascene structure.

9. The connection structure of claim 7, wherein the top via is a single damascene structure.

10. The connection structure of claim 1, wherein the top via is a single damascene structure.

11. A semiconductor device comprising:
a transistor structure;
a 1^{st} metal pattern, in a 1^{st} layer, connected to the transistor structure;
a top via, in a 2^{nd} layer on the 1^{st} layer, connected to the 1^{st} metal pattern;
a super via comprising a lower portion in a 3^{rd} layer on the 2^{nd} layer and an upper portion in a 4^{th} layer on the 3^{rd} layer, the super via being connected to the top via; and
a 2^{nd} metal pattern, in a 5^{th} layer on the 4^{th} layer, connected to the super via.

12. The semiconductor device of claim 11, wherein each of the 3^{rd} layer and the 4th layer is a layer where at least one metal pattern or at least one via is configured to be formed.

13. The semiconductor device of claim 11, further comprising a metal pattern or another top via in the 3^{rd} layer where the lower portion of super via is included,
wherein the metal pattern or the other top via is not connected to the super via, and
wherein the aspect ratio of width and height of the super via is greater than that of the other top via.

14. A method of manufacturing a connection structure of an integrated circuit, the method comprising:
forming a top via at a 2^{nd} layer on a 1^{st} metal pattern at a 1^{st} layer;
forming a super via on the top via, the super via comprising a lower portion at a 3^{rd} layer and an upper portion at a 4^{th} layer; and
forming a 2^{nd} metal pattern, at a 5^{th} layer on the 4^{th} layer, connected to the super via.

15. The method of claim 14, wherein the 3^{rd} layer and the 4^{th} layer each is provided for formation of a metal pattern or a via in the connection structure.

16. The method of claim 14, further comprising forming a metal pattern or another top via in the 3^{rd} layer where the lower portion of super via is included,
wherein the metal pattern or the other top via is not connected to the super via.

17. The method of claim 14, wherein the forming the top via at the 2^{nd} layer comprises:
providing an initial metal structure;
forming a mask pattern on the initial metal structure; and
patterning the initial metal structure using the mask pattern to obtain the top via below the mask pattern on the 1^{st} metal pattern.

18. The method of claim 14, wherein the top via at the 2^{nd} layer may be formed though a single damascene process in which the top via is formed as a single damascene structure.

19. The method of claim 14, wherein the super via is a single damascene structure.

20. The method of claim 14, wherein the 1^{st} metal pattern is a contact structure connected to a gate electrode or a source/drain region of a transistor, and
wherein the 2^{nd} metal pattern is a power line connected to a voltage source.
